(19) United States
(12) Patent Application Publication
(10) Pub. No.: US 2021/0259136 A1
(43) Pub. Date: Aug. 19, 2021

(54) ELECTRONIC DEVICE

(71) Applicant: SHARP KABUSHIKI KAISHA, Sakai City (JP)

(72) Inventors: KOHJI SAWAYAMA, Sakai City (JP); HIDENORI KUWAJIMA, Sakai City (JP); TOMOYA IDE, Sakai City (JP); HIROKI TANABE, Sakai City (JP)

(21) Appl. No.: 17/174,648

(22) Filed: Feb. 12, 2021

(30) Foreign Application Priority Data
Feb. 14, 2020 (JP) 2020-023827

(51) Int. Cl. H05K 7/20; H01L 23/373; H01L 23/367

(52) U.S. Cl. CPC H05K 7/20481; H01L 23/367; H01L 23/3735; H05K 7/205

(57) ABSTRACT

An electronic device comprises an electronic component capable of being a heat source; a substrate on which the electronic component is disposed; and a heat dissipation member that covers, with a heat insulation layer in between, an area including a region of the substrate, at which the electronic component is disposed, and being on a front side or a rear side of the substrate and that is connected to the substrate, wherein the heat dissipation member is formed of a material having thermal conductivity higher than or equal to thermal conductivity of the substrate.

### BACKGROUND

### 1. Field

An aspect, of the present disclosure relates to an electronic device.

### 2. Description of the Related Art

In recent years, with improvement of performance of electronic devices, in particular, small and thin electronic devices such as smartphones, there have been growing concerns about a rise in temperature of a housing surface of an electronic device at the time of use or the like. Particularly, in new use cases such as 5 G communication or recording by an 8K camera, the amount of power consumed by a CPU, a GPU, or the like is especially large, and therefore the temperature of the electronic device becomes locally high, resulting in generation of a so-called heat spot. Generation of a heat spot causes a problem of, for example, a decrease in communication throughput of the electronic device and a deterioration in recording quality of a camera.

Therefore, various measures for avoiding generation of a heat spot are taken regarding electronic devices.

For example, in Japanese Unexamined Patent Application Publication No. 2006-210940, as illustrated in FIG. 6, a stainless steel (SUS) shield 114 that covers a substrate 110 and an electronic component 112 mounted on the substrate 110 are used. The configuration is such that a thermal interface material (TIM) 113 is interposed between the electronic component 112 and the SUS shield 114 and that heat generated by the electronic component 112 is dissipated to the outside of a housing 130 via the TIM 113.

However, in the configuration of the electronic device disclosed in Japanese Unexamined Patent Application Publication No. 2006-210940, low thermal conductivity of the SUS shield 114 makes it difficult for the heat transferred from the electronic component 112 to be spread in the SUS shield 114. Thus, the heat generated by the electronic component 112 is locally transferred to an area of the SUS shield 114, which faces the electronic component 112, via the TIM 113.

Further, the heat generated by the electronic component 112 is locally transferred also to an area of the housing 130, which faces the electronic component 112, and a heat spot (HS) is generated. This results in a problem of a large degradation in performance of an electronic device 1.

An aspect of the disclosure is made in view of the aforementioned problems and suppresses a rise in temperature of an electronic device due to heat generated by an electronic component mounted on the electronic device, thus avoiding a degradation in performance of the electronic device due to the rise in temperature.

### SUMMARY

To address the aforementioned problems, an electronic device according to an aspect of the disclosure includes: an electronic component capable of being a heat source; a substrate on which the electronic component is disposed; and a heat dissipation member that covers, with a heat insulation layer in between, an area including a region of the substrate, at which the electronic component is disposed, and being on a front side or a rear side of the substrate and that is connected to the substrate, in which the heat dissipation member is formed of a material having thermal conductivity higher than or equal to thermal conductivity of the substrate.

### BRIEF DESCRIPTION OF THE DRAWINGS

FIG. 1 is a sectional view of a portion of a side surface of an electronic device 1 according to an embodiment of the disclosure;

FIG. 2 is a plan view of a portion of the electronic device 1 in an area B in FIG. 1;

FIG. 3 is an enlarged sectional view of a portion of the electronic device 1 in an area A1 or an area A2 in FIG. 1;

FIG. 4 is a sectional view of an example of an electronic component 12 mounted on the electronic device 1 according to the embodiment of the disclosure;

FIG. 5 is a sectional view of the side surface of the electronic device 1 according to the embodiment of the disclosure; and

FIG. 6 is a sectional view of a portion of a side surface of an electronic device of a related art.

### DESCRIPTION OF THE EMBODIMENTS

### Embodiment

### <Configuration of Electronic Device>

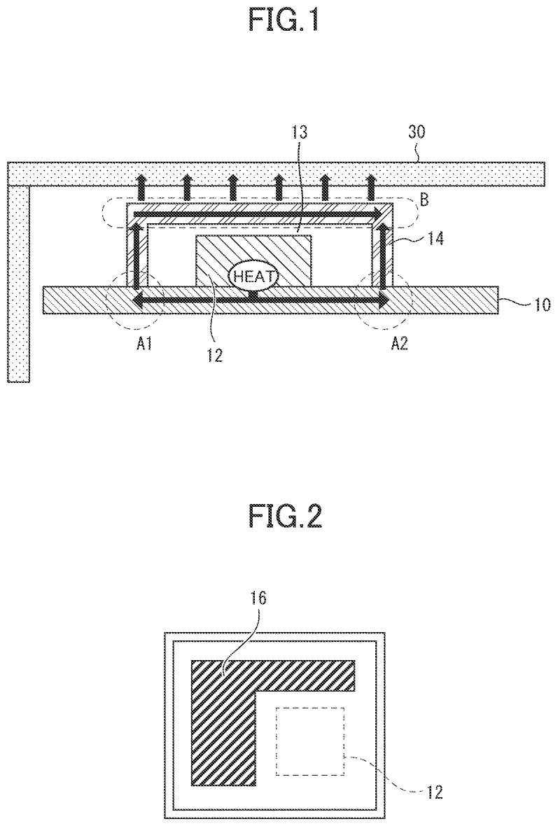

An embodiment of the disclosure will be described below in detail with reference to FIGS. 1 and 2. Note that examples of an electronic device according to an aspect of the disclosure include a smartphone. In addition to the smartphone, various products including a personal computer, a game machine, a tablet terminal, and a household appliance such as a refrigerator are assumed to be the electronic device according to the aspect of the disclosure.

FIG. 1 is a sectional view of an electronic device 1 according to the present embodiment of the disclosure. As illustrated in FIG. 1, the electronic device 1 includes a substrate 10, an electronic component 12, a heat dissipation member 14, and a housing 30.

The substrate 10 is, for example, a rigid substrate. A specific configuration example of the substrate 10 will be described later with reference to a different drawing.

### (Electronic Component)

The electronic component 12 is an electronic component, which can be a heat source, and is disposed on the substrate 10. Whether or not the electronic component 12 generates heat and to what degree the electronic component 12 generates heat vary in accordance with a usage mode.

The electronic component 12 is configured to include a system on chip (SoC) including an integrated circuit such as a central processing unit (CPU) or a graphical processing unit (GPU). However, the present embodiment is not limited thereto, and another electronic component that can be a heat source in accordance with a usage mode may be used. A specific configuration example of the electronic component 12 will be described later with reference to a different drawing.

Note that, in FIG. 1, a size and disposition of the electronic component 12 on the substrate 10 are merely exemplification, and the present embodiment is not limited thereto.

### (Heat Dissipation Member and Heat Insulation Layer)

The electronic device 1 further includes the heat dissipation member 14 that covers, with a heat insulation layer 13 in between, an area including a region of the substrate 10, at which the electronic component 12 is disposed, and being on the front side or rear side of the substrate 10 and that, is connected to the substrate 10.

The heat dissipation member 14 is, for example, a plate member. Here, when it is assumed that a surface of the substrate 10, on which the electronic component 12 is disposed, is referred to as a front surface and that a surface thereof on which the electronic component 12 is not disposed is referred to as a rear surface, the heat dissipation member 14 covers the front surface of the substrate 10 in the example of FIG. 1. However, the present embodiment is not limited thereto, and the configuration may be such that the heat dissipation member 14 covers the rear surface of the substrate 10. More specifically, the configuration may be such that, in FIG. 1, the electronic component 12 is disposed on a surface of the substrate 10, which is opposite to the heat dissipation member 14 illustrated in FIG. 1.

A material constituting the heat dissipation member 14 is formed of a material having thermal conductivity higher than or equal to thermal conductivity of the substrate 10. Here, the thermal conductivity of the substrate 10 is thermal conductivity of a body of the substrate 10, which is mainly formed of a resin, and all metal wires which are provided in the substrate 10. The thermal conductivity is typically about 20 W/mK.

As described below, since many wires and vias (thermal vias) which are formed of a material having high electrical conductivity and thermal conductivity are provided near the electronic component 12 on the substrate 10, thermal conductivity from the electronic component 12 to the heat dissipation member 14 is higher than the thermal conductivity of the entire substrate 10. The thermal conductivity from the electronic component 12 on the substrate 10 to the heat dissipation member 14 is three times or more the thermal conductivity of the entire substrate. Furthermore, when the structure is devised by using sufficient copper for the substrate or by providing thermal vias as many as possible, the thermal conductivity from the electronic component 12 on the substrate 10 to the heat dissipation member 14 is five to ten times the thermal conductivity of the entire substrate. Accordingly, it may be more desirable that the material constituting the heat dissipation member 14 is formed of a material having thermal conductivity higher than or equal to the thermal conductivity from the electronic component 12 on the substrate 10 to the heat dissipation member 14. For example, the heat dissipation member 14 may be constituted by a material having thermal conductivity of 50 W/mK or more. Specific examples of the material of the heat dissipation member 14 include a material containing copper, gold, silver, aluminum, or the like, but the material is not limited thereto.

The heat insulation layer 13 interposed between the electronic component 12 and the heat dissipation member 14 includes at least an air layer or a heat insulation member. The heat insulation layer 13 is, for example, an air. When the heat insulation layer is an air layer, the air layer desirably has a thickness of, for example, 0.3 mm or more or 0.5 mm or more. However, the thickness of the air layer may be 0.3 mm or less. As another example of the heat insulation layer 13, a heat insulation member may be used. More specifically, the configuration may be such that a heat insulation member having a heat insulating property is disposed between the electronic component 12 and the heat dissipation member 14. Moreover, the configuration may be such that the heat insulation layer 13 includes both a heat insulation member and an air layer.

In FIG. 1, a spread of heat generated by the electronic component 12 is indicated by the arrows. The heat generated by the electronic component 12 is spread in the substrate 10 mainly through the wires disposed inside and is dissipated from the substrate 10. Furthermore, the heat spread in the substrate 10 is spread in the entire heat dissipation member 14 from a connection portion of the substrate 10 and the heat dissipation member 14. The heat spread throughout the entire heat dissipation member 14 is spread in a large area of the housing 30 and is also dissipated from the housing 30.

Since the heat dissipation member 14 is constituted by a material having high thermal conductivity as described above, the heat transferred to the heat dissipation member 14 is quickly and smoothly spread in the heat dissipation member 14, and it is therefore possible to suppress a local rise in temperature of the heat dissipation member 14 in an area facing the electronic component 12. Thus, also in the housing 30, it is possible to suppress generation of a heat spot (HS) in an area near the electronic component 12.

The heat insulation layer 13 being interposed between the electronic component 12 and the heat dissipation member 14 makes it possible to suppress local transfer of the heat generated by the electronic component 12 to the heat dissipation member 14 in an area near the electronic component 12, furthermore, to the housing 30 and to suppress generation of a heat spot (HS) in an area near the electronic component 12.

### (Insulation Sheet)

FIG. 2 is a plan view in which the heat dissipation member 14 in an area B of the electronic device 1 in FIG. 1 is viewed from the surface on the substrate 10 side. As illustrated in FIG. 2, on the surface of the heat dissipation member 14 on the substrate 10 side, an insulation sheet 16 is provided in an area other than an area in which the heat dissipation member 14 faces the electronic component 12. With the insulation sheet 16, it is possible to avoid electrical connection between a component mounted on the substrate and the heat dissipation member 14. Note that the insulation sheet 16 is not provided in the area, in which the heat dissipation member 14 faces the electronic component 12, to ensure a sufficient thickness of the heat, insulation layer 13 between the electronic component 12 and the heat dissipation member 14. When the heat insulation layer 13 has a sufficient thickness between the electronic component 12 and the heat dissipation member 14 without providing the insulation sheet 16 in the area, it is possible to suppress transfer of the heat generated by the electronic component 12 to the heat dissipation member 14 and the housing 30.

### (Connection of Substrate 10 and Heat Dissipation Member 14)

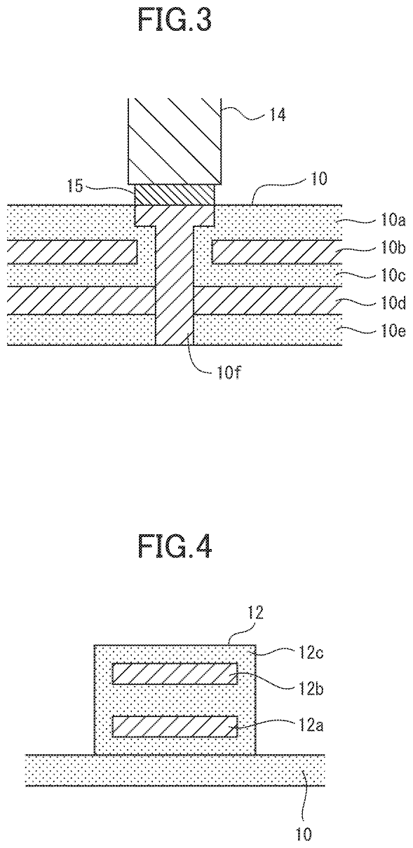

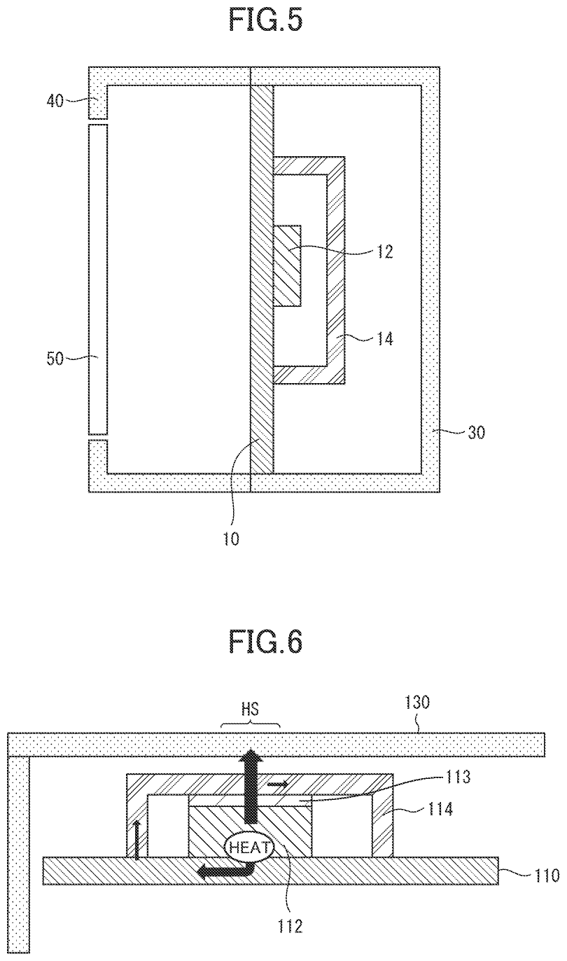

Subsequently, an example of connection of the substrate 10 and the heat dissipation member 14 will be described with reference to FIG. 3.

FIG. 3 is an enlarged sectional view of a portion in the area Al indicated by a circle in FIG. 1. A similar configuration is provided also in a portion in the area A2 indicated by a circle in FIG. 1.

As illustrated in FIG. 3, the substrate 10 is a multilayer substrate including a wiring layer 10b and a ground layer 10d and may include one or more vias (in particular, a via that improves a heat dissipation effect is also referred to as a thermal via) 10f that connect the ground layer 10d and the heat dissipation member 14. Specifically, the substrate 10 is configured by laminating a first resin layer 10a, the wiring layer 10b, a second resin layer 10c, the ground layer 10d, and a third resin layer 10e.

The wiring layer 10b is a layer in which a wire electrically connecting the electronic component 12 and an element, which are mounted on the substrate 10, to each other is disposed. The wiring layer 10b is formed of a material having conductivity, such as copper. As illustrated in FIG. 3, the wiring layer 10b is disposed between the first resin layer 10a and the second resin layer 10c.

The ground layer 10d is a layer in which a ground connected to the electronic component 12 or the element which is mounted on the substrate 10 is disposed. The ground layer 10d is formed of a material having conductivity, such as copper. As illustrated in FIG. 3, the ground layer 10d is disposed between the second resin layer 10c and the third resin layer 10e. However, the structure illustrated in FIG. 3 is an example of a structure of a multilayer substrate, and a structural order and the number of layers of the resin layers, the wiring layer, and the ground layer are not limited to the structure illustrated in FIG. 3.

In the via 10f, the interior of a hole that connects the rear surface and the front surface of the substrate 10 is filled with a material, for example, metal such as copper, which has high electrical conductivity and thermal conductivity. Here, the via 10f may be a through hole (through-hole via) that passes through the substrate 10 from the rear surface to the front surface. The through hole may be configured to have an inner surface covered with a material such as copper, which has electrical conductivity and thermal conductivity.

As illustrated in FIG. 3, the via 10f is disposed such that the via 10f is in contact with the ground layer 10d and is not in contact with a wire in the wiring layer 10b.

Further, an end of the via 10f on the front surface of the substrate 10 is in contact with the heat dissipation member 14. In addition, the end of the via 10f and the heat dissipation member 14 are fixed to each other by, for example, a solder 15.

With the aforementioned configuration, it is possible to conduct the heat generated by the electronic component 12 to the ground layer 10d provided in the substrate 10 and efficiently transfer the heat from the ground layer 10d to the heat dissipation member 14 via the via 10f. Thus, as described above, since many wires and vias 10f are provided near the electronic component 12 on the substrate 10, the thermal conductivity from the electronic component 12 to the heat dissipation member 14 is higher than the thermal conductivity of the entire substrate 10. Note that, as the number of the vias 10f in the substrate 10 increases, the thermal conductivity of the entire substrate 10 improves, and a heat dissipation effect also becomes higher. Thus, it is suitable to provide the vias 10f as many as possible.

Note that, since many wires and vias (thermal vias) 10f which are formed of a material having high electrical conductivity and thermal conductivity are provided near the electronic component 12 on the substrate 10, thermal conductivity of an area from the electronic component 12 to the heat dissipation member 14 is higher than the thermal conductivity of the entire substrate 10. Accordingly, as described above, it is desirable that the material of the heat dissipation member 14 is constituted by the material having thermal conductivity higher than or equal to the thermal conductivity from the electronic component 12 on the substrate 10 to the heat dissipation member 14.

### (Configuration of Electronic Component)

FIG. 4 is a sectional view of an example of the electronic component 12. The electronic component 12 may include an integrated circuit layer 12a in which at least an integrated circuit is formed and a memory layer 12b in which at least memory is formed and which is disposed further than the integrated circuit layer 12a from the substrate 10. The integrated circuit layer 12a may be, for example, a system on chip (SoC). The integrated circuit layer 12a and the memory layer 12b are surrounded by a resin layer 12c having low thermal conductivity. Thus, in the aforementioned configuration, heat generated in the integrated circuit layer 12a is obstructed by the resin layer 12c and the memory layer 12b and is difficult to be dissipated from the side opposite to the substrate 10.

However, with the configuration of the present embodiment, the heat generated by the electronic component 12 is able to be suitably removed from the substrate 10 side. Thus, even the above-described electronic component is able to suppress a rise in temperature of the electronic device.

### (Configuration of Electronic Device)

FIG. 5 is a sectional view of the side surface of an example of the electronic device 1 of the disclosure. The electronic device 1 includes a housing that accommodates at least the substrate 10 and the heat dissipation member 14 and a display panel 50 that is disposed on a surface side of the housing. The electronic device 1 dissipates heat of the electronic component 12 from a portion of the housing, which is disposed on a side opposite to the display panel 50. That is, the heat dissipation member 14 may be disposed on a side of the substrate 10 opposite to the display panel 50.

As illustrated in FIG. 5, the electronic device 1 according to the present example includes the housing 30 as a first housing and further includes a housing 40 as a second housing. The material of the second housing 40 may be similar to the material constituting the housing 30. As the material of the first housing 30 and the second housing 40, metal, a resin, and other materials may be used. Moreover, an opening portion is formed in the second housing 40, and the display panel 50 is disposed in the opening portion.

Note that, although no component is illustrated on a second housing 40 side of the substrate 10 in FIG. 5, the present embodiment is not limited thereto, and the electronic device 1 according to the present example may include one or more components on the second housing 40 side of the substrate 10.

With the aforementioned configuration, the heat generated by the electronic component 12 is able to be dissipated in a wide range from the first housing 30 (the right side in FIG. 5) through the heat dissipation member 14. It is therefore possible to dissipate the heat from the first housing 30, which ordinarily serves as a grip portion for a user, without generating a heat spot. In this manner, according to the aforementioned example, it is possible to suppress generation of a heat spot in the first housing 30 on a grip portion side and suitably dissipate the heat generated by the electronic component 12.

### [Conclusion]

### [Aspect 1]

An electronic device of an aspect of the disclosure includes: an electronic component capable of being a heat source; a substrate on which the electronic component is disposed; and a heat dissipation member that covers, with a heat insulation layer in between, an area including a region of the substrate, at which the electronic component is disposed, and being on a front side or a rear side of the substrate and that is connected to the substrate, in which the heat dissipation member is formed of a material having thermal conductivity higher than or equal to thermal conductivity of the substrate.

### [Aspect 2]

In the electronic device according to the aspect of the disclosure, the heat dissipation member may be formed of a material having thermal conductivity of 50 W/mK or more.

With the aforementioned configuration, heat generated by the electronic component is efficiently transferred to the heat dissipation member, and it is possible to suppress a local rise in temperature. Further, the heat insulation layer being provided between the electronic component and the heat dissipation member is able to suppress local transfer of the heat generated by the electronic component to the heat dissipation member. Accordingly, it is possible to suppress generation of a heat spot in the electronic device.

### [Aspect 3]

In the electronic device according to the aspect of the disclosure, the material of the heat dissipation member may contain copper.

With the aforementioned configuration, when copper whose electrical conductivity and thermal conductivity are both high and which is inexpensive is used for the heat dissipation member, it is possible to suppress a rise in temperature of the electronic device.

### [Aspect 4]

In the electronic device according to the aspect of the disclosure, the heat insulation layer may include at least an air layer or a heat insulation member.

With the aforementioned configuration, by arranging nothing between the electronic component and the heat dissipation member to provide an air layer or by arranging a heat insulation member having low thermal conductivity, it is possible to suppress local transfer of heat from the electronic component to the heat dissipation member and suppress generation of a heat spot in the electronic device.

### [Aspect 5]

The electronic device according to the aspect of the disclosure may further include an insulation sheet in an area other than an area, in which the heat dissipation member faces the electronic component, on a surface of the heat dissipation member on a side of the substrate.

With the aforementioned configuration, the insulation sheet is able to suppress electrical connection between a component mounted and disposed on the substrate and the heat dissipation member. By providing no insulation sheet between the electronic component that can generate heat and the heat dissipation member, it is possible to provide a heat insulation layer having a sufficient thickness between the electronic component and the heat dissipation member.

### [Aspect 6]

In the electronic device according to the aspect of the disclosure, the substrate may be a multilayer substrate including a wiring layer and a ground layer, and include one or more vias that connect the ground layer and the heat dissipation member.

With the aforementioned configuration, it is possible to efficiently transfer the heat generated by the electronic component from the via to the heat dissipation member.

### [Aspect 7]

In the electronic device according to the aspect of the disclosure, the electronic component may include an integrated circuit layer in which at least an integrated circuit is formed, and a memory layer in which at least memory is formed and which is disposed further than the integrated circuit layer from the substrate.

With the aforementioned configuration, heat generated by the electronic component is able to be efficiently emitted from the substrate side where there is nothing to hinder heat dissipation.

### [Aspect 8]

The electronic device according to the aspect of the disclosure may further include: a housing that accommodates at least the substrate and the heat dissipation member; and a display panel disposed on a surface side of the housing, in which heat of the electronic component may be dissipated from a portion of the housing, which is disposed on a side opposite to the display panel.

With the aforementioned configuration, it is possible to emit the heat in a wide range from a side on which a user ordinarily grips the electronic device, that is, the side opposite to the display panel. It is therefore possible to avoid the problem, for example, that the gripping hand of the user is heated.

The disclosure is not limited to each of the embodiments described above and may be modified in various manners within the scope indicated in the Claims, and an embodiment achieved by appropriately combining techniques disclosed in each of different embodiments is also encompassed in the technical scope of the disclosure. Further, by combining the techniques disclosed in each of the embodiments, a new technical feature may be formed.

The present disclosure contains subject matter related to that disclosed in Japanese Priority Patent Application JP 2020-023827 filed in the Japan Patent Office on Feb. 14, 2020, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An electronic device comprising:
an electronic component capable of being a heat source;
a substrate on which the electronic component is disposed; and
a heat dissipation member that covers, with a heat insulation layer in between, an area including a region of the substrate, at which the electronic component is disposed, and being on a front side or a rear side of the substrate and that is connected to the substrate, wherein
the heat dissipation member is formed of a material having thermal conductivity higher than or equal to thermal conductivity of the substrate.

2. The electronic device according to claim 1, wherein the heat dissipation member is formed of a material having thermal conductivity of 50 W/mK or more.

3. The electronic device according to claim 1, wherein the material of the heat dissipation member contains copper.

4. The electronic device according to claim 1, wherein the heat insulation layer includes at least an air layer or a heat insulation member.

5. The electronic device according to claim 1, further comprising an insulation sheet in an area other than an area, in which the heat dissipation member faces the electronic component, on a surface of the heat dissipation member on a side of the substrate.

6. The electronic device according to claim 1, wherein the substrate
is a multilayer substrate including a wiring layer and a ground layer, and
includes one or more vias that connect the ground layer and the heat dissipation member.

7. The electronic device according to claim 1, wherein the electronic component includes
an integrated circuit layer in which at least an integrated circuit is formed, and
a memory layer in which at least memory is formed and which is disposed further than the integrated circuit layer from the substrate.

8. The electronic device according to claim 1, further comprising:
a housing that accommodates at least the substrate and the heat dissipation member; and
a display panel disposed on a surface side of the housing, wherein
heat of the electronic component is dissipated from a portion of the housing, which is disposed on a side opposite to the display panel.
